(19) United States
(12) Patent Application Publication
(10) Pub. No.: US 2005/0199282 A1
(43) Pub. Date: Sep. 15, 2005

(54) Photovoltaic-embedded surface

(75) Inventors: Jonathan Oleinick, Boca Raton, FL (US); Eric J. Wilhelm, Oakland, CA (US)

Correspondence Address: DAVIDSON, DAVIDSON & KAPPEL, LLC, 485 SEVENTH AVENUE, 14TH FLOOR, NEW YORK, NY, 10018, US

(73) Assignee: Oleinick Energy, LLC, Boca Raton, FL (US)

(21) Appl. No.: 11/078,004

(22) Filed: Mar. 11, 2005

Related U.S. Application Data
(60) Provisional application No. 60/521,207, filed on Mar. 11, 2004.

(51) Int. Cl. H01L 31/00

(52) U.S. Cl. 136/256; 136/291; 136/244

(57) ABSTRACT

An integrated solar power system that provides electricity to external electrical devices has a trafficable surface formed from a plurality of roadway panels arranged with respect to each other. Each roadway panel has a solar energy collector, a layer of translucent and protective material covering the solar energy collector, the material being sufficiently translucent to allow passage of light therethrough for absorption of light by said solar energy collector and sufficiently protective to withstand the loads and the impact of pedestrian and vehicular traffic and having a sufficient coefficient of friction to allow passage thereon of pedestrians and vehicles without slippage, and an electrical conductor for extracting electrical power from the solar energy collector. Each roadway panel may be modularly connected to others. The roadway panel provides solar energy to at least one external electrical device or solar power storage member.

### CROSS-REFERENCE TO RELATED APPLICATION

This application claims the benefit of U.S. Provisional Patent Application No. 60/521,207, filed Mar. 11, 2004.

### BACKGROUND OF INVENTION

This invention relates to a photovoltaic solar energy system, and in particular to the incorporation of a photovoltaic system into paved trafficable surfaces.

Solar energy is generally harnessed in two ways. Thermal solar energy typically uses dark-colored surfaces to collect heat from sunlight and then transfers that heat via liquids to a location where it can be used. Photovoltaic solar energy typically uses semiconductor materials to translate the photon energy found in sunlight to direct current electrical energy. This invention concerns the use of photovoltaic solar energy.

Photovoltaic devices or solar cells absorb sunlight and convert it directly into useable electrical energy. A typical photovoltaic cell is a solid-state device in which a junction is formed between adjacent layers of semiconductor materials doped with specific atoms. When light energy or photons strike the semiconductor, electrons are dislodged from the valence band. These electrons, collected by the electric field at the junction, create a voltage that can be put at work in an external circuit. The basic scientific principles that underlie this effect are well known and understood to those in the art.

Solar cells are used to provide power in various applications, for example in small electronic devices such as calculators. Many applications use arrays of photovoltaic cells or panels connected to each other in accordance with current and voltage requirements of the application. For example, it is a known practice to harness solar energy by mounting photovoltaic panels where they are most likely to receive a maximum amount of sunlight without interference, e.g., from trees or nearby construction, such as on building roofs or other elements of buildings, or on ground-based racks on unused areas, like highway median strips or sides of parking garages. For buildings and systems already connected to the national power grid, these panels are connected to “balance of system” units like wires, inverters and AC/DC disconnects that conduct the generated electricity to the home, transform it from direct current to alternating current, and provide the utility company an option to turn off the electricity from the solar system.

Locally produced, or “distributed generation”, solar power has three significant advantages. First, since it does not have to travel through the power grid, it does not suffer from the approximately 15% power deterioration caused by such travel. Second, distributed generation reduces load strain on the power grid, the major cause of blackouts such as the one in the northeastern U.S. and Canada in September 2003. Third, solar power generated in “solar farms”, or utility-sized centralized generation plants, is sold to utilities at wholesale energy prices. Solar power that is produced by homes or communities can often qualify for “net-metering”, meaning that the electricity that the homes and businesses do not use can be sold back to the local utility at retail prices, which are on average three times higher than wholesale prices. Therefore, distributed generation, located at or near buildings, generates energy that is often times three times as valuable as centralized distributed energy produced by solar farms. These advantages of distributed generation are advantages for the utility company that runs the power, the people and companies that use the power, and the city municipalities in which they all live and work.

However, there are several problems with photovoltaic systems that are found mostly on roof- and ground-based racks. First, individually mounting solar panels on roofs is relatively expensive and can, in some cases, be a significant portion of the overall system cost. Even mitigation of the costs, such as by use of cheaper racks or adhesives, by incorporation of photovoltaic materials into roofing tile, or by integrating solar cells into cement and other building materials, is often still unacceptable, because removing old roof tiles and installing new tiles is still cost prohibitive. In addition, photovoltaic tiles are still often unsightly and still do not solve the problem of limited space. Moreover, cement-photovoltaic material combinations are low-yielding and difficult to work with. Furthermore, and more fundamentally, individually connecting systems for houses, as well as installing individual meters and filing appropriate state and regulatory paperwork, can be inefficient and costly.

Second, many areas of high electricity use have limited roof space and limited unused ground space in which to place the relatively large solar panels and associated rack systems. Thus, the limited available space on buildings in many urban and suburban areas for placement of solar panels generally would not generate sufficient electricity to make use of such devices worthwhile. This limits the amount of locally produced solar energy to which those buildings have access.

Third, some residential, commercial, community and governmental customers find the look of solar panels on roofs or separately placed ground-based rack-systems unappealing and unattractive in their neighborhood or environment and, therefore, shun solar power use. Moreover, solar panels using ground-based rack-systems are much too delicate to withstand foot traffic, let alone vehicle traffic.

Thus, in urban and suburban areas, where sidewalks, walkways, streets or other paved surfaces are prevalent, it would be desirable to use those surfaces for harnessing solar energy. There have been some attempts to incorporate photovoltaic materials into these paved surfaces. For example, U.S. Pat. No. 5,074,706 (Paulos), U.S. Pat. No. 5,984,570 (Parashar) and U.S. Pat. No. 6,602,021 (Kim) show photovoltaic materials embedded in roadway markers. More pertinent are U.S. Patent Application Publications Nos. 2003/0090896 (Sooferian) and 2003/0137831 (Lin), which show photovoltaic materials embedded in walkway panels.

However, the previous attempts to incorporate photovoltaic materials into walkways and other paved areas have been unsuccessful because existing photovoltaic materials are too fragile to single-handedly withstand traffic loads. Even switching photovoltaic materials from crystalline silicon, which is extremely fragile, to thin-film semiconductors, which are less fragile, or covering the photovoltaic materials with coatings like Teflon, still do not result in surfaces that can withstand the load of traffic, both human and vehicular, borne by most streets and walkways. In addition, attempts to reduce the vulnerability of solar panels to traffic loads by chemically combining cement and other materials directly with photovoltaic material have resulted in products that are inefficient or too expensive to make.

Furthermore, these structures are all designed to be self-powering, i.e., that the photovoltaic materials incorporated therein provide sufficient electricity and power only for the light sources contained therein. No attempts have been made thus far to use walkways, streets or other heavily-trafficked paved surfaces for providing electricity to surrounding homes and businesses, while also protecting the photovoltaic materials incorporated therein from the bulk of traffic loads.

Finally, selling solar panels to individual commercial and residential owners is inefficient, and adoption in the U.S. has been slow. Solar farms increase the use of solar energy but do not offer many of the advantages that should come with distributed generation of solar energy (as described above). Also, the additional monies to support the solar farms are received from individual homes and businesses on a one-by-one basis. Introducing a product that can be used by entire cities, including streets, as well as to homes, businesses, airports, shopping malls, and many other customers, could help speed up adoption.

### SUMMARY OF INVENTION

Accordingly, it is one object of the present invention to combine weaker photovoltaic materials side-by-side with stronger non-photovoltaic construction materials to build hybrid paved surfaces that can withstand strong traffic loads but can also capture sunlight to transform it into energy.

It is a further object of the present invention to combine photovoltaic material and construction materials (e.g., asphalt, concrete, brick, rubber, ceramic, and others) to form photovoltaic-embedded pavement that can generate solar energy from the surfaces of streets, walkways, driveways, runways and other paved areas or potentially paved areas.

In accordance with these and other objects of the invention, the invention provides a photovoltaic solar energy system that is incorporated into paved surfaces. In particular, the invention is directed to the incorporation of a photovoltaic system into paved, i.e., non-photovoltaic, trafficable surfaces such as streets, highways, walkways, sidewalks, parking lots, driveways and runways, and to methods of preparing surfaces and photovoltaic materials for such a system. The system of the present invention is able to generate electricity inexpensively and conveniently, and protect the photovoltaic materials from the bulk of traffic loads and from environmental elements that could potentially damage the photovoltaic materials.

The combined surface contains both photovoltaic material, which transforms energy from the sun into electricity, and a hard paving material, such as brick, asphalt or concrete, which bears the traffic load and protects the photovoltaic material. The combined surface incorporates a plurality of photovoltaic sections or panels, comprising photovoltaic materials covered with a smooth but tractioned light-transmissive surface. The photovoltaic materials are connected to a balance of system unit for a photovoltaic energy system.

In preferred embodiments, the system can be retrofitted onto existing paved surfaces or can be installed as part of new surfaces.

Embedding solar panels into streets, highways, walkways, sidewalks, parking lots, runways, driveways and other paved surfaces using the method described herein can solve the problems discussed above. First, integrating photovoltaic materials into paved surfaces provides significant additional area from which to generate solar energy than would otherwise have been available through roof space and unused area alone. Second, integrating solar panels into streets provides an aesthetic alternative to roofs and ground racks for homeowners, building owners, communities and other customers. Third, in some cases, photovoltaic modules in pavement can be installed, cleaned and maintained cheaply, since they can be installed in large batches, do not need elaborate racking systems, can be standardized across projects, and are easier to access than rooftops and most racked systems. Fourth, the suggested method of integrating solar panels into roads and pavement uses the harder non-photovoltaic substances to protect the photovoltaic substance from loads.

### BRIEF DESCRIPTION OF THE DRAWINGS

The above and other objects and advantages of the invention will be apparent upon consideration of the following detailed description, taken in conjunction with the accompanying drawings, in which the reference characters refer to like parts throughout and in which:

FIG. 1 shows a house with a driveway that incorporates photovoltaic materials;

FIGS. 2A and 2B show perspective views of photovoltaic-embedded roadway surfaces having a mixture of photovoltaic-incorporating and non-photovoltaic-incorporating surfaces;

FIG. 3A shows a cross-sectional view of a photovoltaic panel;

FIG. 3B shows a perspective view of a photovoltaic panel;

FIGS. 4A and 4B show cross-sectional views of photovoltaic panels having frictional elements on their upper surfaces;

FIG. 5 shows a cross-sectional view of a border clamp for a photovoltaic panel;

FIG. 6 shows a configuration of a grid-connected solar electricity system;

FIG. 7A shows a cross-sectional view of a second embodiment of a photovoltaic panel; and

FIG. 7B shows a cross-sectional view of a third embodiment of a photovoltaic panel.

### DETAILED DESCRIPTION OF THE INVENTION

This invention contemplates the incorporation of photovoltaic materials into all paved trafficable surfaces, which refer to surfaces that are intended to carry pedestrian or vehicular traffic or that are potentially suitable for carrying pedestrian or vehicular traffic. Trafficable surfaces are those that can sustain loads perpendicular to the surface and have a coefficient of friction that is acceptable or similar to that normally used for surfaces that carry pedestrian or vehicular traffic, including but not limited to walkways, sidewalks, driveways, streets, highways, parking lots and runways, as well as basketball courts, tennis courts and urban baseball fields. Accordingly, discussions herein regarding the composition of the paved surfaces or of the photovoltaic-incorporated portions thereof are applicable to all paved surfaces, unless specifically stated otherwise. Thus, discussions herein shall generally refer to a “roadway” to generically designate these paved, trafficable surfaces.

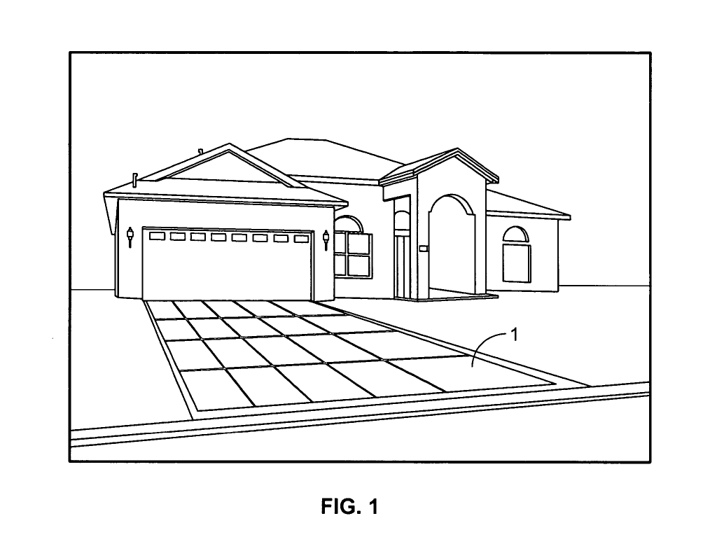

Referring to the drawings, FIG. 1 shows a roadway 1, in this instance the driveway of a house, that incorporates photovoltaic materials in accordance with one preferred embodiment of the invention. In one embodiment, the photovoltaic-embedded driveway 1 can have a dark, non-reflective surface that, both from afar and from close distances, appears much like dark concrete or asphalt and blends nicely with suburban surroundings and public pedestrian walkways. The roadway 1 can have other appearances depending upon the precise composition of the materials used. In the embodiment of FIG. 1, the photovoltaic materials either were incorporated into the driveway at the time of installation thereof or were retrofitted onto the existing paved driveway, such as by adhering them to the existing pavement with commercially available tar adhesives, at some point after installation

A photovoltaic-embedded roadway surface can comprise from about 0.01% to about 99.99% of its surface incorporating photovoltaic material and the remainder not incorporating photovoltaic material. In a preferred embodiment of the invention, the entire roadway (as much as 100%) can be composed of photovoltaic-incorporated portions.

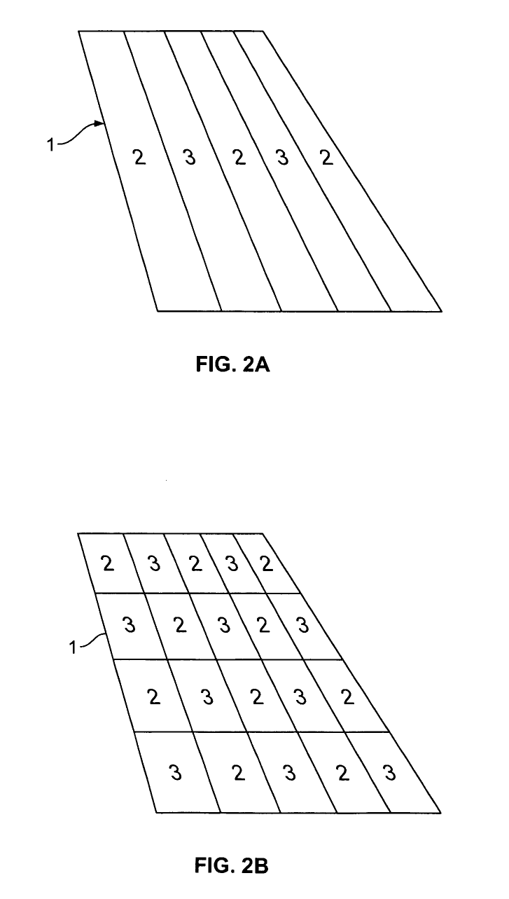

In another preferred embodiment, the photovoltaic-embedded roadway can be composed of a mixture of non-photovoltaic-incorporated portions, e.g., standard concrete or asphalt, and photovoltaic-incorporated portions. In such an embodiment, the standard concrete or asphalt portions and the photovoltaic-incorporated portions can be interspersed or alternated throughout the area of the roadway. For example, FIGS. 2A and 2B show perspective views of roadway surfaces 1 having a mixture of photovoltaic-incorporating and non-photovoltaic-incorporating portions. In FIG. 2A, the portions that incorporate photovoltaic materials 2 and the portions that do not incorporate photovoltaic materials 3 are alternating, and in FIG. 2B, the portions that incorporate photovoltaic materials 2 and the portions that do not incorporate photovoltaic materials 3 are laid out in somewhat of a checkerboard pattern. In both cases, the photovoltaic-embedded roadway 1 has approximately 50% of the surface area of the roadway surface incorporating photovoltaic elements 2 and approximately 50% of the surface area not incorporating photovoltaic elements 3.

The amount of roadway surface covered with each type of material and the respective shapes (e.g., circles, lines, rectangles, strips, squares, triangles, etc.) of the photovoltaic and non-photovoltaic material surfaces, as well as the chosen locations of each type of surface within the roadway, will be determined by engineering and aesthetic choices based on external factors. Among these factors are the weight of objects that will be traveling on the surface (e.g., pedestrians, cars, trucks, airplanes, etc.), the portions of the roadway where those objects will and will not be most often traveling, the year-round weather conditions of the area of installation (both average and extremes), the year-round sun exposure conditions of each portion of the area of installation, the elevation of the area of installation, the type of use of the surface (e.g., residential, commercial, governmental, municipal, and others), the preferences of customers, users, installers or other relevant parties, and any applicable municipal or government regulation. For example, it is preferred to place the photovoltaic-incorporated portions of the roadway where it is believed that a greater amount of sun will shine or where it is believed that the heaviest industrial loads will not travel the most frequently.

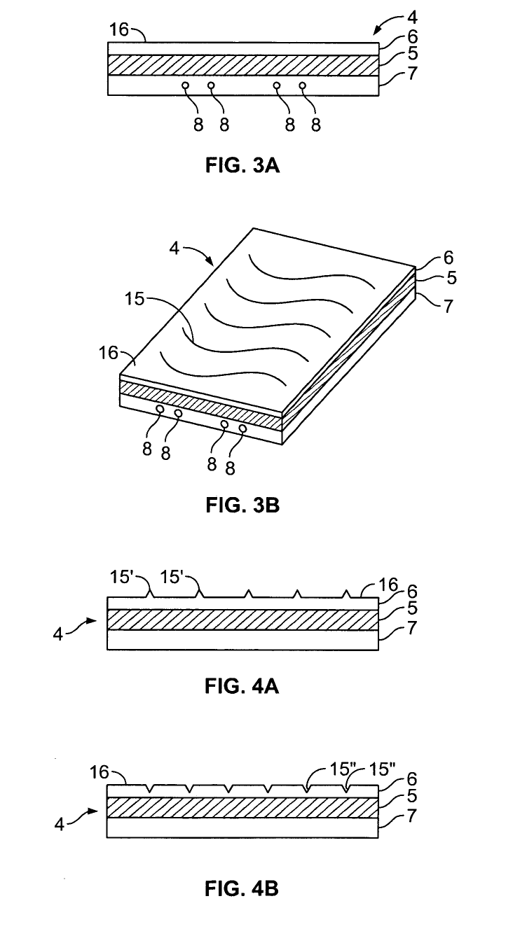

In one preferred embodiment, photovoltaic materials are incorporated into roadway surfaces by way of photovoltaic panels. FIGS. 3A and 3B show cross-sectional and perspective views of a photovoltaic panel 4. In a preferred embodiment, each photovoltaic panel 4 comprises a “sandwich-type” construction. As shown in FIG. 3A, the photovoltaic panel 4 is typically comprised of three layers: the photovoltaic material 5 in the middle, a protective coating 6 above it, and a lower, electrical area 7 below it.

The photovoltaic material 5 in the middle of the photovoltaic panel 2 sandwich can be any solar energy collecting material that absorbs sunlight and converts it to electricity through photovoltaic action, typically referred to as an electrical photovoltaic cell or “solar cell”. The photovoltaic material 5 can be prepared by any of the known means in the art and use any of the existing photovoltaic technologies, and may include a solar energy collector and a solar power storage device, such as a capacitor or any device known in the art, for storing the solar energy received from the solar energy collector. The photovoltaic material 5 may include semiconductor materials such as, but not limited to, monocrystalline silicon, polycrystalline silicon, thin-film amorphous silicon, copper-indium-gallium-selenide or related materials, and cadmium telluride, as well as any others that are well known in the art.

Photovoltaic material 5 can come from any manufacturer, such as United Solar Ovonic LLC, of Auburn Hills, Mich. (“Uni-Solar”). One preferred photovoltaic material is Uni-Solar module PVL-31. One or more different types of photovoltaic cells may be incorporated within each photovoltaic roadway panel 4.

The photovoltaic material 5, e.g., one or more photovoltaic cells, can be cut or formed into the necessary size or shape needed to integrate it into the surface of roadway 1. This process can be done before or at the time of incorporation into the non-photovoltaic portions 3 of the roadway 1. The manner of preparation will depend on the type of photovoltaic material used. It should be noted that the photovoltaic material 5 can extend over the entire area of the panel 4, from edge to edge, thus maximizing the photovoltaic potential of each roadway panel 4.

The top layer 6 of photovoltaic panel 4 is formed of one or more layers of a coating that protects the photovoltaic material 5 underneath it from being damaged by the natural elements, by the traffic that travels on the roadway or by any other forces. Accordingly, the top, protective layer 6 should preferably be comprised of any substance or combination of substances that is sufficiently strong so as to bear the load of the expected traffic and protect the photovoltaic materials 5 from weather factors, abrasions and direct contact from traffic without scratching, cracking, breaking or otherwise failing.

In addition, in order for sunlight to penetrate through the top layer 6 and reach the photovoltaic material 5 beneath it for generating solar electricity, the top layer 6 should preferably be clear or translucent, or sufficiently near clear or near translucent so that sufficient sunlight can pass therethrough and generate enough electricity to make the installation of this surface worthwhile. Top layer 6 should also be relatively easy to clean so as to ensure that it can be cleaned often and easily to ensure that sufficient light travels therethrough.

Examples of preferred suitable materials that are acceptable for top layer 6 include clear plastic, Teflon®, acrylic, polycarbonate, abrasion resistant versions of the above materials (i.e., those materials coated with an anti-scratch laminate), the above materials with a tight grid of 0.25″ through holes, Diamonex®-coated polycarbonate, fiberglass (4 oz. S) in epoxy on polycarbonate, tempered glass, annealed glass, and 5 mm glass balls in epoxy on annealed glass, with a most preferred material being polycarbonate-backed acrylic. The above materials were all subjected to repeated abrasion tests from sand, gravel, rocks and other road grit, stress tests by being run over by a car tire under 750 lbs of load 20,000 times, impact tests by high forces, friction tests, and light transmission tests before and after each abrasion test. In addition, the tester runs in a tight radius, so the wear is accelerated approximately threefold.

One of skill in the art could determine through experimentation precise combination of these and other materials that would provide for protective layer 6 the optimum combination of scratch and abrasion resistance, impact and stress strength, cost and light permeability, based upon the desired characteristics. It is preferable that the protective layer 6 be very serviceable, such that abrasion thereof due to exposure over time to sand, gravel and vehicle travel, which can impede sunlight from being transmitted therethrough, can be readily removed by sandblasting and resurfacing to give it a brand new appearance and restore light transmissiveness.

As stated, because photovoltaic material 5 can extend over the entire area of the panel 4, from edge to edge, protective layer 6 should also extend from edge to edge to completely cover the photovoltaic material 5 thereunder.

Furthermore, in order for traffic to travel on photovoltaic materials 2, the top surface of each photovoltaic panel 4 must provide sufficient friction to the pedestrian and vehicular traffic passing thereon so as to prevent slippage of people and vehicles. Accordingly, the material of protective coating layer 6 should provide sufficient friction, either by the nature of its composition or through subsequent treatment, so as not to impede the passage of traffic due to slippage.

In certain preferred embodiments, as shown in FIG. 3B, protective layer 6 comprises a series of surface frictional elements 15 formed into its upper surface 16. In certain embodiments, frictional elements 15 are particularly useful on surfaces that are very strong, abrasive-resistant and light-permeable but either do not by themselves provide enough traction for traffic to pass thereon or for which additional traction is desired. Frictional elements 15 serve to provide additional traction or friction for traffic to pass thereon and can be added to the upper surface of all protective coating layer 6 materials.

Frictional elements 15 can be elements that project upwards from top layer 16 or indentations or grooves that are formed into coating layer 6. Alternatively, frictional elements can be external materials that are set onto or within the upper surface of coating layer 6. Frictional elements 15 can also have any cross-sectional shapes, so long as they are shaped so as to provide sufficient friction to coating layer 6 while not impeding the transmission of light therethrough to photovoltaic material 5 beneath it. Frictional elements 15 are formed into protective coating layer 6 in any desired direction, pattern or shape, such as straight lines, curved lines, crossed lines, circles or any other geometric shapes and patterns, long or short, so as to perform the desired function.

For example, as shown in the cross-sectional view of FIG. 4A, elements 15′ can be projections that extend upwards from the upper surface 16 of protective layer 6. In FIG. 4A, elements 15′ shown can be the cross-sectional shape of elongated raised strips that project upward from surface 16, as shown in FIG. 4A, or can be the cross-sectional shape of individual raised elements, such as spikes that project upward from surface 16. Frictional elements 15′ can be external materials, such as spikes or elongated strips or bars, that are set onto or within the upper surface of protective layer 6, such as by first forming grooves into surface 16 and then setting spikes or bars within the grooves, or by any other known method. These spikes or bars can be formed of any acceptable durable material, such as stainless steel or polycarbonate.

Alternatively, as shown in the cross-sectional view of FIG. 4B, elements 15″ can be formed into the upper surface 16 of protective layer 6, as elongated grooves or individual indentations that are cut into upper surface 16. This option might be the least expensive, as it does not require any additional materials beyond the upper layer 6 itself, but also carries the risk that stones and other small particles could get trapped within these grooves or indentations.

In addition, in certain embodiments, frictional elements 15 can provide added refraction for sunlight as it shines upon the photovoltaic panel 4 to allow it to more directly impinge upon photovoltaic material 5 beneath coating layer 6. For example, as shown in FIG. 4B, sunlight that is directed toward photovoltaic panel 4 at an angle, such as during the later afternoon or during the winter, after passing through protective layer 6, do not normally impinge upon photovoltaic material 5 at a 90° angle, thereby not generating as much electricity as it otherwise could. In this embodiment, angled sunlight that enters frictional elements 15″ may be refracted downward towards photovoltaic material 5 at a 90° angle so as to enable the angled sunlight to generate more electricity.

In certain preferred embodiments, frictional elements 15 are provided at only specific locations along the surface of coating layer 6 where traffic is known to pass. In other embodiments, frictional elements 15 are formed all along and across the complete upper surface of coating layer 6. Alternatively, frictional elements 15 may be formed all along the complete upper surface 16 of coating layer 6 of certain photovoltaic panels, along only parts of the upper surface 16 of coating layer 6 of other photovoltaic panels, and not at all on the upper surface 16 of coating layer 6 of still other photovoltaic panels.

In order to allow the roadway to be used for various purposes, coating layer 6 should also be able to accept colors or paint, either applied to its upper surface 16 or incorporated with its material. For example, when used for roadways, top layer 6 should bear appropriate lane and traffic markings. Alternatively, if used as a surface for basketball courts, tennis courts or urban baseball fields, coating layer 6 should bear appropriate markings for the relevant sport. If the markings are incorporated therein, they would be prepared within the material of coating layer 6 prior to construction and the panels arranged appropriately.

As shown in FIGS. 3A and 3B, the lower, electrical area 7 preferably contains wiring 8 and wire casings sufficient to connect photovoltaic material 5, e.g., one or more photovoltaic cells, to an output terminal, such as a nearby building or energy grid, as are well known in the art, and perhaps also to each other. In other embodiments, wiring 8 may connect photovoltaic material 5, or a group of nearby photovoltaic materials 5, to electrical devices, power storage devices, such as a local capacitor or other device well known in the art, that in turn may be connected to a nearby building or energy grid, as are well known in the art. In further embodiments, the wiring 8 might extend into areas of non-photovoltaic material 3 in order to reach suitable end points, such as one or more external electrical devices, power storage devices or electrical grids, or for any number of engineering or aesthetic reasons or applications.

The electrical area 7, beneath the photovoltaic material 5, can in certain embodiments be just a region whose volume is defined by the photovoltaic material 5 above it and the sides and bottom of the material within which the photovoltaic panel 4 happens to be set. Alternatively, electrical area 7 can be an actual enclosed or partially-enclosed chamber. If required, this electrical area 7 can be filled with filler similar to casing material, insulation, any weight-bearing substance, air, additional wires, coils, metals or other substances to ensure that the photovoltaic material 5 rests directly on an even, supportive material to prevent buckling, for example, as shown in FIG. 3B.

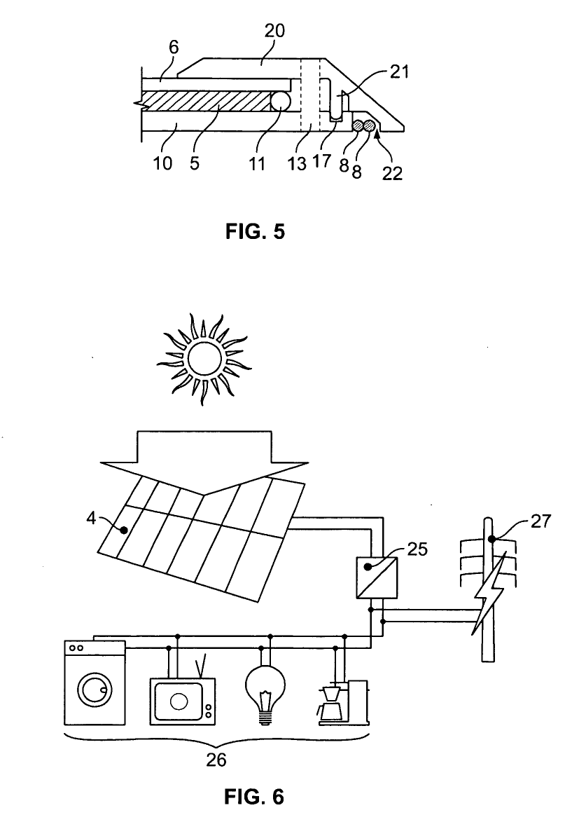

Photovoltaic panels 2 can be assembled from the layers discussed above in any number of ways. In one preferred embodiment, the photovoltaic material or module is first adhered to a layer of backing 10, such as a PVC or aluminum body (see FIG. 5). While this backing can be somewhat stiff or rigid, it must also be sufficiently flexible so as to handle or conform to large scale variations in the roadway surface. The backing can have the appropriate wiring embedded therein, for example along its underside or upperside. Copper foil conductors can be used to connect the solar module's solder tabs to wires at the bottom of the backing to provide the basis for the later electrical connections to the building or electricity grid. In certain embodiments, a sealing member, such as an O-ring, formed from rubber or another appropriate material, may be clamped between the protective layer 6 and the photovoltaic material 5, or surrounding the photovoltaic material 5, to provide for a seal against entry of moisture and miscellaneous particles (for example, see 11 in FIG. 5).

Next, the protective coating layer 6, such as an acrylic or whichever material is chosen, must be attached to the photovoltaic material 5. Where an O-ring is used, the coating layer 6 is placed on the O-ring surrounded photovoltaic material 5. In certain embodiments, strips or bars, formed from any suitable material, e.g., stainless steel or polycarbonate, can be set within, or placed on top of, the coating layer 6 (if not already done previously) in order to provide traction and to prevent slipping of traffic when the acrylic surface is wet.

In one embodiment, in order to adhere and/or secure the layers of photovoltaic panel 2 to each other, i.e., the photovoltaic material 5 to the protective coating 6 above it and perhaps also to the lower, electrical area 7 below it, relevant and adequate adhesives, sealants, clamps, grips and/or supports will be used. If adhesives or sealants are used, care should be taken to place the adhesives or sealants between the upper layer 6 and the photovoltaic material 5 in a manner such that it does not interfere with the light that passes through top layer 6 to photovoltaic material 5 beneath it. For example, gaskets, glue or sealant can be placed at the periphery of the layer assembly to seal the layers to each other and from the surrounding environment. In another embodiment, the protective coating can be laminated onto the photovoltaic material 5 during the manufacture of the photovoltaic material.

In another preferred embodiment, the layers of photovoltaic panel 2 are tightly clamped to each other, i.e., protective layer 6 is held against the photovoltaic material 5, by methods that are well known in the art, such as by the clamping action of screws or bolts.

In certain embodiments, such as where panels 4 are placed over an existing roadway 1, the edges of the clamps may act as ramps so that a car driving over the border do not damage the edges of the panels 4. In this embodiment, border clamps whose edges are ramps (herein called clamp-ramps) may be utilized around the edges or borders of panels 4 in order to allow vehicular traffic to ascend onto and descend from the panels 4 without damaging the edges of the photovoltaic roadway panels 4. FIG. 5 shows a cross-section of a roadway panel wherein clamp-ramp 20 is used. In this embodiment, clamp ramp 20 secures coating layer 6 onto photovoltaic material 5, which is shown having been pre-adhered to a backing 10, such as a PVC body. In addition, where photovoltaic material 5 has been surrounded by an O-ring 11, clamp-ramp 20 holds the coating layer 6 against the O-ring 11.

For stability, clamp ramp 20 may be secured to the backing 10 by any known securing means, such as screws, nails or studs 13. For additional stability, clamp ramp 20 may also be installed into grooves 17 formed around the perimeter edges of the backing 10 by way of extension legs 21, shown in cross-section in FIG. 5. The clamp ramp 20 also provides a cavity or channel 22, such as at the leading edge of the clamp ramp 20 along the perimeter of the panel 4, for the purpose protecting and hiding electrical wiring 8 that runs from photovoltaic material 5 to locations external to the body of panel 4.

This process of photovoltaic-casing construction can occur before or at the time of installation. As an option, individual photovoltaic panels 4 can then be attached together by wire or other means to assist in the transportation and installation process.

Each photovoltaic panel 4 can have any desired shape, such that one or more panels can be combined, so as to provide the roadway surface with the desired total area, design and shape incorporating photovoltaic elements. Photovoltaic panels 4 can be constructed into the top layer of new roads, walkways, driveways, runways or other paved surfaces or can be retrofitted onto existing paved surfaces. In a preferred embodiment, especially where photovoltaic panels 4 are modular, each photovoltaic panel 4 can have the same default size and shape, such as a panel having the dimensions 5 ft.×1.5 ft. In another preferred embodiment, where photovoltaic panels 4 are laid in accordance with a specific design, photovoltaic panels 2 can be prefabricated in any desired shapes to fit together in a specific pattern, similar to standard floor tiles.

The non-photovoltaic material, which makes up the bulk of the cross-sectional area of the roadway, can be any one of or a combination of any number of paving or construction materials, such as plastics, brick, concrete, asphalt, rubber and others that are well known in the construction art. In a preferred embodiment, the non-photovoltaic material is used to support traffic loads on the surface and below the photovoltaic portions of the roadway, and is preferably situated within the roadway so as to absorb most of the weight load of the traffic.

In one preferred embodiment, photovoltaic panels 4 can be simply laid next each other to or among other non-photovoltaic panels or surfaces. This is done preferably only when a flat surface is already present, such as pre-laid cement, concrete or asphalt or any other surface, including earth. It is preferred that cement, concrete or asphalt be pre-laid prior to installation of the photovoltaic surface 2. It is preferable that each photovoltaic panel 4 be bonding or sealed to each adjacent photovoltaic panel 4, so as to prevent leakage of potentially destructive materials between photovoltaic panels 4.

In this embodiment, it is preferred that photovoltaic panels 4 be modular so that installation can be quick and simple. In such an embodiment, for example as shown in FIG. 4A, each photovoltaic panel 4 has wiring connections 8 at the edges thereof that connect to similar wiring connections 8 at the edges of adjacent panels 4 via specialized or modular connectors, sometimes called “easy connectors”, as are known in the field of modular electrical connections For example, adjacent photovoltaic panels 4 may be connected in series or in parallel, and one skilled in the art would prepare the wiring connections appropriately and even label the appropriate sockets at the edge of each photovoltaic panel 4 accordingly. In such a way, photovoltaic panels 4 may be laid adjacent to and electrically attached to each other quickly and conveniently. Should specific roadway or sports surface markings be desirable, modular photovoltaic panels 4 can be colored appropriately and the specific order of placement of these modular photovoltaic panels 4 can be planned in advance.

In another preferred embodiment, the solar energy materials are embedded among the non-photovoltaic roadway material. In one embodiment, each photovoltaic panel 4 could rest directly on the base material underneath the roadway 1 and be merely adjacent to the non-photovoltaic materials 3. In a preferred embodiment, each photovoltaic panel 4 could be supported by part of the non-photovoltaic materials 3 and embedded within the non-photovoltaic roadway material 1, such as within specially configured indentations or channels that securely hold the photovoltaic panel 4. The walls of these indentations or channels could be covered with photovoltaic material casing, which can be a range of common adhesive materials, metals, building grout, rubber, or other materials that would form an adequate casing for the photovoltaic material and associated wires and coating. Wiring 8 and wire casings are connected to nearby electrical devices, buildings, power storage devices or energy grids, and an inverter is used to connect the photovoltaic panels 4 to the grid, as known by those skilled in the art.

The indentation or channel for the photovoltaic panel 4 can be created in pre-existing or new surfaces through any number of methods. For existing roads, one example is to cut or slice out sections of the roadway using a strong cutting device, and then to insert the prefabricated photovoltaic panel into the channel so that the result is a flat, even surface of photovoltaic and non-photovoltaic material. Another example would be to lay a thin film of new non-photovoltaic standard paving material, such as cement or asphalt, on a preexisting surface and then create indentations or channels in the fresh non-photovoltaic material before it hardens, using objects or machines of appropriate size. In a similar fashion, indentations or channels can be formed during the construction of new roadways

Once indentations or channels have been formed, photovoltaic panels 2 and associated wiring 8 would then be added in any number of ways, as known in the art. In each case, the placing of the electrical components around the photovoltaic panels 2 would take place using common electrical installation techniques. Connections between photovoltaic panels 2 and between the full solar installation and the inverter may be made in electrical junction boxes, which are common in outdoor electrical wiring.

FIG. 6 shows a configuration of a grid-connected solar electricity system. When the sun shines onto the surface of the roadway, light penetrates the top, protective layer 6 of a the photovoltaic panel 4 and impinges upon the photovoltaic material 5 under protective layer 6, causing the generation of an electric current that is then taken by the wiring 8 to the balance of electrical system components 25, which may be structurally integrated with the surface components or situated on the side of the paved area, based on engineering, aesthetic, space and other concerns. As is well known in solar energy systems, the balance of electrical system components 25 for most photovoltaic-embedded systems will contain an inverter to transform the direct current (DC) generated from the photovoltaic-material into alternating current (AC) current that can be used by users or by the electricity grid. Depending on electrical code, AC and DC disconnects can also be part of the balance of system components. Other components, like timers, meters, metal protective casings, or other components either necessary for installation, regulated by governing bodies or other relevant reasons, can also be part of the balance of electrical system components.

Energy is then conducted out of the balance of electrical system components by wires or other electrical circuitry that lead either to one or more electrical devices 26, such as street and signal lights or other nearby municipal uses, cathodic protection devices or snow/ice heaters, to buildings or to power storage devices, or to an electricity grid 27. Optional meters with optional wireless or wired communication devices to measure and communicate the current produced by the system or used by a building can be placed before or after the energy reaches the balance of electrical system components.

Due to exposure to sunlight and operation of photovoltaic materials 5, the temperature of photovoltaic surfaces 2 will typically experience a rise, leading to decreased efficiency of the photovoltaic materials 5 therein. Accordingly, in accordance with a preferred embodiment of the invention, heat is dissipated from each photovoltaic panel 4 into the ground, e.g., into the base material or the non-photovoltaic roadway material 1. In a first embodiment, the bottom surface of the photovoltaic panels 4 is rested against the ground or some other comparable heat sink, to conduct heat away from the photovoltaic material 5. In this embodiment, it is preferable to form that photovoltaic material 5 or its stiff backing 10 from a highly thermally conductive material, such as aluminum or any other conductive material, and to increase the surface area contact of the photovoltaic material 5 with the ground.

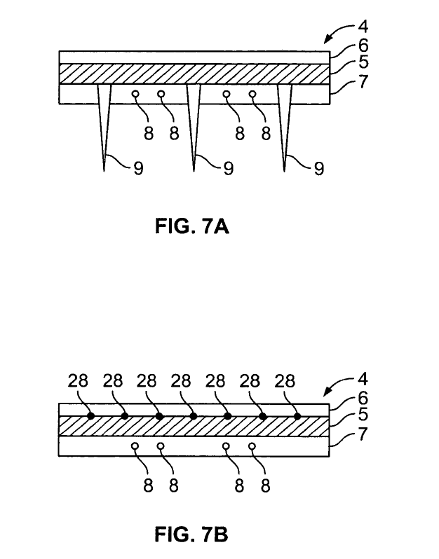

However, dissipation of heat from the photovoltaic material may be difficult because the lower, electrical layer 7 of the photovoltaic panel 4 is situated between the photovoltaic material 5 and the ground or non-photovoltaic roadway material 1. In another embodiment, therefore, dissipation of heat from the photovoltaic material 5 can be accomplished by elongated posts, or stakes, 9 that contact the photovoltaic material 5 and protruded into the ground, as shown in FIG. 7A. In a preferred embodiment, these stakes 9 are formed from a heat-conductive material, such as metal. These stakes 9 provide for increased surface area contact between the photovoltaic material 5 and the ground or the non-photovoltaic roadway material 1 to assist in conducting heat away from the photovoltaic material 5. It is also preferable to minimize (and insulate) the electrical layer 7 between the photovoltaic material 5 and the ground to avoid unintended heating thereof.

One advantage of the fact that the temperature of photovoltaic panels 2 will rise, although mitigated somewhat by the heat-dissipating stakes, is that snow- and ice-covered surfaces will be less of a problem. As a result of the heat generated by the photovoltaic panels 4, snow and ice will tend to melt much more easily on the inventive surfaces than on standard paved surfaces that do not incorporate photovoltaic materials. However, in a more preferred embodiment, as shown in FIG. 7B, a network of heating wires 28 may be set between the protective coating 6 and the photovoltaic material 5. Wires 28 are small in diameter, as is known in the art, such that the group of wires has a low profile. At appropriate times, these electrically conductive wires 28, which draw power from the photovoltaic materials 5 (and, potentially, external sources, if energy generated by the photovoltaic material 5 is not sufficient), may be powered on or off remotely to provide heat underneath the protective coating 6 and to melt snow or ice that has formed thereon.

Maintenance of a photovoltaic-embedded surface will vary based on weather conditions, type of traffic, amount of usage, location, accessibility and other factors. Maintenance activities can include, but not be limited to, cleaning of photovoltaic materials, checking on operations of solar system, replacing photovoltaic material, casing, wiring, protective coating and other components, and sandblasting and resurfacing of the protective coating.

As a result of the novel construction described herein, there will be no significant decline in comfort for the people or vehicles that use the photovoltaic-embedded surface and no significant reduction in energy conversion of the photovoltaic materials during use or after continued use. However, more land will be available for use by solar panels, and those solar panels will now be placed in a more aesthetically pleasing way, costs will be lowered for installation and repair, and the frailty problem of photovoltaic material will be partially solved and compensated.

The photovoltaic-embedded system described herein will enable the use of existing photovoltaic materials in the millions of miles of paved surfaces around the world to exploit untapped solar energy for electricity, thereby preventing environmentally harmful burning of fossil fuels for the creation of energy.

Thus, a photovoltaic solar energy system that is incorporated into paved surfaces has been provided. One skilled in the art will appreciate that the present invention can be practiced by other than the described embodiments, which are presented for purposes of illustration and not limitation.

1. An integrated solar power system for providing electricity from a trafficable surface to external electrical devices, comprising:
at least one roadway panel comprising
a solar energy collector substantially across the width thereof;
a layer of translucent and protective material substantially across the width thereof and covering said solar energy collector, said material being sufficiently translucent to allow passage of light therethrough for absorption of light by said solar energy collector, being sufficiently protective to withstand the loads and the impact of pedestrian and vehicular traffic, and having a sufficient coefficient of friction to allow passage thereon of pedestrians and vehicles without slippage; and
an electrical conductor associated with said solar energy collector for extracting electrical power therefrom;
said at least one roadway panel being arranged with respect to each other to form a trafficable surface; and
said at least one roadway panel providing solar energy to at least one external electrical device or solar power storage member.

2. The integrated solar power collector system of claim 1 wherein said layer of material covering said solar energy collector comprises a plurality of layers of translucent material.

3. The integrated solar power collector system of claim 1 wherein said at least one roadway panel comprises a plurality of roadway panels arranged with respect to each other among a plurality of non-photovoltaic roadway panels.

4. The integrated solar power collector system of claim 1 wherein said at least one roadway panel comprises a plurality of roadway panels arranged with respect to each other on a pre-laid trafficable surface.

5. The integrated solar power collector system of claim 4 wherein said pre-laid trafficable surface comprises a plurality of indentations into each of which one of said plurality of roadway panels is set.

6. The integrated solar power collector system of claim 1 wherein said at least one roadway panel comprises a plurality of modular roadway panels that are arranged with respect to each other to form a trafficable surface.

7. The integrated solar power collector system of claim 6 wherein said electrical conductor of each modular roadway panel may be modularly connected to the electrical conductor of an adjacent modular roadway panel.

8. The integrated solar power collector system of claim 1 wherein said layer of material comprises frictional elements disposed on the upper surface thereof.

9. The integrated solar power collector system of claim 8 wherein said frictional elements comprise indentations or grooves formed into the upper surface of said layer.

10. The integrated solar power collector system of claim 8 wherein said frictional elements comprise individual or elongated raised elements that project upward from the upper surface of said layer.

11. The integrated solar power collector system of claim 1 wherein said trafficable surface is a street, highway, walkway, sidewalk, parking lot, driveway or runway.

12. The integrated solar power collector system of claim 1 further comprising at least one heat-conductive post that extends downward from the solar energy collector of each roadway panel to assist in dissipation of heat from the solar energy collector.

13. The integrated solar power collector system of claim 1 wherein said at least one external electrical device is a building or an electrical power network.

14. A method of collecting solar power in a trafficable surface and providing electricity to external electrical devices, comprising:
providing at least one roadway panel comprising
a solar energy collector substantially across the width thereof;
a layer of translucent and protective material substantially across the width thereof and covering said solar energy collector, said material being sufficiently translucent to allow passage of light therethrough for absorption of light by said solar energy collector, being sufficiently protective to withstand the loads and the impact of pedestrian and vehicular traffic, and having a sufficient coefficient of friction to allow passage thereon of pedestrians and vehicles without slippage; and
an electrical conductor associated with said solar energy collector for extracting electrical power therefrom;
arranging said at least one roadway panel with respect to each other to form a trafficable surface; and
providing solar energy from said at least one roadway panel to at least one external electrical device or solar power storage member.

15. The method of claim 14 wherein said step of providing at least one roadway panel comprises the step of associating an electrical conductor with said solar energy collector for extracting electrical power therefrom.

16. The method of claim 14 wherein said step of providing at least one roadway panel comprises attaching said solar energy collector and said layer of translucent and protective material together such that any space between them is sealed.

17. The method of claim 14 wherein said step of providing at least one roadway panel comprises laminating said layer of translucent and protective material layer onto said solar energy collector.

18. The method of claim 14 wherein said step of arranging said at least one roadway panel comprises arranging a plurality of roadway panels with respect to each other among a plurality of non-photovoltaic roadway panels.

19. The method of claim 14 wherein said step of arranging at least one roadway panel comprises arranging a plurality of roadway panels with respect to each other on a pre-laid trafficable surface.

20. The method of claim 19 wherein said step of arranging at least one roadway panel comprises the steps of:
forming a plurality of indentations into said pre-laid trafficable surface; and
setting each of a plurality of roadway panels into one of said plurality of indentations.

21. The method of claim 14 wherein said step of arranging at least one roadway panel comprises arranging a plurality of modular roadway panels with respect to each other to form a trafficable surface.

22. The method of claim 21 wherein said step of arranging a plurality of modular roadway panels with respect to each other comprises modularly connecting the electrical conductor of each modular roadway panel to the electrical conductor of an adjacent modular roadway panel.

23. The method of claim 14 wherein said step of providing at least one roadway panel further comprises disposing frictional elements onto the upper surface of the covering material of each said roadway panel.

24. The method of claim 23 wherein said step of disposing comprises forming indentations or grooves into the upper surface of said layer.

25. The method of claim 23 wherein said step of disposing comprises providing individual or elongated raised elements that project upward from the upper surface of said layer.

26. The method of claim 14 wherein said step of providing at least one roadway panel further comprises providing at least one heat-conductive post that extends downward from the solar energy collector to assist in dissipation of heat from the solar energy collector.

27. The method of claim 14 wherein said step of providing said stored solar energy to at least one external electrical device comprises providing said stored solar energy to a building or an electrical power network.

28. A roadway panel for use in providing electricity from a trafficable surface to an external electrical device, comprising:
a solar energy collector substantially across the width thereof;
a layer of translucent and protective material substantially across the width thereof and covering said solar energy collector, said material being sufficiently translucent to allow passage of light therethrough for absorption of light by said solar energy collector, being sufficiently protective to withstand the loads and the impact of pedestrian and vehicular traffic, and having a sufficient coefficient of friction to allow passage thereon of pedestrians and vehicles without slippage; and
an electrical conductor associated with said solar energy collector for extracting electrical power therefrom and for providing said electrical power to an external device;
said roadway panel being adapted to be set with respect to other roadway panels or non-photovoltaic roadway panels to form a trafficable surface; and
said roadway panel providing solar energy to at least one external electrical device or solar power storage member.

29. The roadway panel of claim 28 wherein said covering material further comprises frictional elements disposed on the upper surface thereof.

30. The roadway panel of claim 29 wherein said frictional elements comprise indentations or grooves formed into the upper surface of said layer.

31. The roadway panel of claim 29 wherein said frictional elements comprise individual or elongated raised elements that project upward from the upper surface of said layer.

32. The roadway panel of claim 28 further comprising at least one heat-conductive post that extends downward from the solar energy collector of each roadway panel to assist in dissipation of heat from the solar energy collector.

33. The roadway panel of claim 28 wherein said roadway panel is modular such that it can be arranged with respect to other modular roadway panels to form a trafficable surface.

34. The roadway panel of claim 33 wherein said wherein said electrical conductor of each modular roadway panel may be modularly connected to the electrical conductor of an adjacent modular roadway panel.

35. The integrated solar power collector system of claim 1 further comprising at least one wire electrically coupled to said solar energy collector and positioned between said solar energy collector and said layer of material, for providing heat to the upper surface of said roadway panel.

36. The method of claim 14 further comprising the step of positioning at least one wire electrically coupled to said solar energy collector between said solar energy collector and said layer of material to provide heat to the upper surface of said roadway panel.

37. The roadway panel of claim 28 further comprising at least one wire electrically coupled to said solar energy collector and positioned between said solar energy collector and said layer of material, for providing heat to the upper surface of said roadway panel.
